(19) United States
(12) Patent Application Publication
(10) Pub. No.: US 2020/0020530 A1
(43) Pub. Date: Jan. 16, 2020

(54) LASER IRRADIATION DEVICE, METHOD OF MANUFACTURING THIN FILM TRANSISTOR, PROGRAM, AND PROJECTION MASK

(71) Applicant: V Technology Co., Ltd., Yokohama-shi (JP)

(72) Inventor: Michinobu Mizumura, Yokohama-shi (JP)

(21) Appl. No.: 16/487,289

(22) PCT Filed: Feb. 20, 2018
(86) PCT No.: PCT/JP2018/006071

§ 371 Date: Aug. 20, 2019

(30) Foreign Application Priority Data
Feb. 21, 2017 (JP) 2017-029889

(51) Int. Cl. H01L 21/02

(52) U.S. Cl. CPC H01L 21/02678

(57) ABSTRACT

A laser irradiation device includes a light source that generates laser light; a projection lens that emits the laser light onto a predetermined area of an amorphous silicon thin film deposited on a thin film transistor; and a projection mask pattern that is disposed in the projection lens and transmits the laser light in a predetermined projection pattern, wherein the projection mask pattern includes auxiliary patterns disposed in the surroundings of a transmission area corresponding to the predetermined area in addition to the transmission area and transmits the laser light.

### TECHNICAL FIELD

This disclosure relates to formation of a thin film transistor and, more particularly, to a laser irradiation device, a method of manufacturing a thin film transistor, and a program that forms a polysilicon thin film by emitting laser light onto an amorphous silicon thin film on a thin film transistor.

### BACKGROUND

As a thin film transistor having an inverted staggered structure, there is a thin film transistor in which an amorphous silicon thin film is used for a channel region. However, since an amorphous silicon thin film has a low electron mobility when the amorphous silicon thin film is used for a channel region, there is a disadvantage in that the mobility of electric charge in a thin film transistor becomes low.

Thus, there is a method of polycrystallizing a predetermined area of an amorphous silicon thin film by heating it instantaneously using laser light, forming a polysilicon thin film having a high electron mobility, and using the polysilicon thin film for a channel region.

For example, Japanese Unexamined Patent Application Publication No. 2016-100537 discloses a process of forming an amorphous silicon thin film in a channel region and thereafter performing laser annealing by emitting laser light such as excimer laser to the amorphous silicon thin film to be crystallized into a polysilicon thin film in accordance with melting and solidifying in a short time is performed. JP '537 describes that, by performing that process, a channel region between a source and a drain of a thin film transistor can be formed as a polysilicon thin film having a high electron mobility, and the operation of the transistor can be performed at a high speed.

In the thin film transistor described in JP '537, while laser light is emitted to a channel region between a source and a drain for laser annealing, there are instances in which the the intensity of the emitted laser light is not constant, and the degree of crystallization of polysilicon crystal is biased within the channel region. Particularly, when laser light is emitted through a projection mask, the intensity of the laser light emitted onto the channel region may not be constant in accordance with the shape of the projection mask and, as a result, the degree of crystallization in the channel region is biased.

For this reason, when characteristics of a formed polysilicon thin film are not uniform, there is a possibility that deviations will occur in the characteristics of individual thin film transistors included in a substrate in accordance therewith. As a result, there is a problem of occurrence of display blurring in liquid crystal generated using the substrate.

It could therefore be helpful to provide a laser irradiation device, a method of manufacturing thin film transistors, a program, and a projection mask capable of inhibiting variations in characteristics of a plurality of thin film transistors included in a substrate by decreasing deviations in characteristics of laser light emitted to a channel region.

### SUMMARY

We thus provide:
A laser irradiation device including: a light source that generates laser light; a projection lens that emits the laser light onto a predetermined area of an amorphous silicon thin film deposited on a thin film transistor; and a projection mask pattern disposed in the projection lens and transmits the laser light in a predetermined projection pattern, wherein the projection mask pattern includes auxiliary patterns disposed in the surroundings of a transmission area corresponding to the predetermined area in addition to the transmission area and transmits the laser light.
The projection lens may be a plurality of microlenses included in a microlens array that can split the laser light, and each of a plurality of masks included in the projection mask pattern may correspond to each of the plurality of microlenses.
The projection mask pattern may include auxiliary patterns having an approximately rectangular shape disposed in a long side direction or a short side direction of a transmission area in addition to the transmission area having an approximately rectangular shape and having a width narrower than the transmission area.
The projection mask pattern may include second auxiliary patterns disposed in a short side direction of the transmission area in addition to first auxiliary patterns disposed in a long side direction of the transmission area having an approximately rectangular shape.
In the projection mask pattern, a width or a size of the auxiliary patterns may be determined on the basis of an energy of the laser light in the predetermined area.
In the projection mask pattern, a plurality of light shielding parts shielding the laser light may be disposed in edge areas within the transmission area in a long side direction or a short side direction of the transmission area.
In the projection mask pattern, a plurality of light shielding parts shielding the laser light may be disposed in edge areas within the transmission area in a long side direction and a short side direction of the transmission area, and densities of the light shielding parts disposed in the edge areas in the long side direction and the edge areas in the short side direction may be different from each other.
In the projection mask pattern, a density of the light shielding parts disposed within the transmission area may be determined in accordance with an energy of the laser light in the predetermined area.
A method of manufacturing a thin film transistor includes: a generation step of generating laser light; a transmission step of transmitting the laser light in a predetermined projection pattern disposed in a projection lens; and an emission step of emitting the laser light transmitted through the predetermined projection pattern onto a predetermined area of an amorphous silicon thin film deposited in a thin film transistor, wherein, in the transmission step, the laser light is transmitted through auxiliary patterns disposed in the surroundings of a transmission area corresponding to the predetermined area in addition to the transmission area.
A program causes a computer to execute: a generation function of generating laser light; a transmission function of transmitting the laser light in a predetermined projection pattern disposed in a projection lens; and an emission function of emitting the laser light transmitted through the predetermined projection pattern onto a predetermined area of an amorphous silicon thin film deposited in a thin film transistor, wherein, in the transmission function, the laser light is transmitted through auxiliary patterns disposed in the surroundings of a transmission area corresponding to the predetermined area in addition to the transmission area.
A projection mask is disposed in a projection lens emitting laser light, the projection mask including: a first mask pattern that transmits the laser light in a predetermined projection pattern for a predetermined area of an amorphous silicon thin film deposited in a thin film transistor; and a second mask pattern disposed in the surroundings of the first mask pattern corresponding to the predetermined area in addition to the first mask pattern and transmits the laser light.

The projection lens may be a plurality of microlenses included in a microlens array that can split the laser light, and each of a plurality of masks included in the first mask pattern may correspond to each of the plurality of microlenses.

The second mask pattern may include auxiliary patterns having an approximately rectangular shape disposed in a long side direction or a short side direction of a transmission area in addition to the transmission area having an approximately rectangular shape and having a width narrower than the transmission area.

The second mask pattern may include patterns disposed in a short side direction of the transmission area in addition to patterns disposed in a long side direction of the transmission area having an approximately rectangular shape.

A width or a size of the second mask pattern may be determined on the basis of an energy of the laser light in the predetermined area.

A plurality of light shielding parts shielding the laser light may be disposed in edge areas within the transmission area in a long side direction or a short side direction of the transmission area.

In the second mask pattern, a plurality of light shielding parts shielding the laser light may be disposed in edge areas within the transmission area in a long side direction and a short side direction of the transmission area, and densities of the light shielding parts disposed in the edge areas in the long side direction and the edge areas in the short side direction may be different from each other.

In the second mask pattern, a density of the light shielding parts disposed within the transmission area may be determined in accordance with an energy of the laser light in the predetermined area.

A laser irradiation device, a method of manufacturing thin film transistors, a program, and a projection mask capable of inhibiting variations in characteristics of a plurality of thin film transistors included in a substrate by decreasing deviations in characteristics of laser light emitted to a channel region are provided.

### BRIEF DESCRIPTION OF THE DRAWINGS

FIG. 1 is a diagram illustrating a configuration of a laser irradiation device according to a first example.

FIG. 2 is a diagram illustrating a configuration of a thin film transistor according to the first example in which a predetermined area is processed by annealing.

FIG. 3 is a diagram illustrating a configuration of a substrate to which a laser irradiation device according to the first example emits laser light.

FIG. 4 is a diagram illustrating a configuration of a microlens array according to the first example.

FIG. 5 is a diagram illustrating an example of a projection mask included in a projection mask pattern.

FIG. 6 is a graph representing an energy status of laser light in a predetermined area.

FIG. 7 is a diagram illustrating a configuration of a projection mask 150 included in a projection mask pattern according to the first example.

FIG. 8 is a graph representing an energy status of laser light in a predetermined area according to the first example.

FIG. 9 is a diagram illustrating a configuration of a projection mask when auxiliary patterns are disposed in a widthwise direction of a transmission area according to the first example.

FIG. 10 is a diagram illustrating a configuration of a projection mask according to a second example.

FIGS. 11(a)-11(e) are diagrams illustrating a configuration of a projection mask according to a third example.

FIG. 12 is a diagram illustrating a configuration of a laser irradiation device according to a fourth example.

### REFERENCE SIGNS LIST

10 laser irradiation device
11 laser light source
12 coupling optical system
13 microlens array
14 laser light
15 projection mask pattern
150 projection mask
151 transmission area
152 light shielding area
153 auxiliary pattern
154 light shielding portion
17 microlens
18 projection lens
20 thin film transistor
22 polysilicon thin film
23 source
24 drain
30 substrate

### DETAILED DESCRIPTION

Hereinafter, examples will be specifically described with reference to the drawings.

### FIRST EXAMPLE

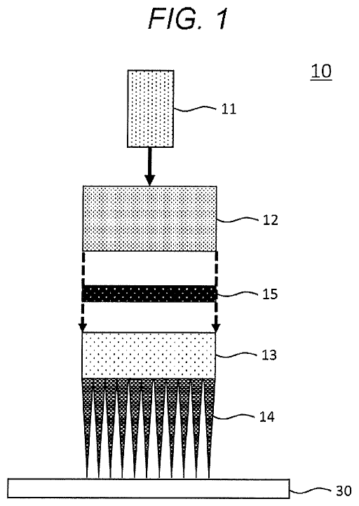

FIG. 1 is a diagram illustrating a configuration example of a laser irradiation device 10 according to a first example.

In the first example, the laser irradiation device 10 is a device, for example, used to performing annealing by emitting laser light onto an area in which a channel region is planned to be formed and polycrystallizing the area in which a channel region is planned to be formed in a process of manufacturing a semiconductor device such as a thin film transistor (TFT) 20.

The laser irradiation device 10, for example, is used when a thin film transistor of a pixel of a peripheral circuit of a liquid crystal display device or the like is formed. When such a thin film transistor is formed, first, a gate electrode formed of an Al metal film or the like is formed as a pattern on a substrate 30 through sputtering. Then, by using a low-temperature plasma CVD method, a gate insulating film formed from a SiN film is formed on an entire face on the substrate 30. Thereafter, an amorphous silicon thin film is formed on the gate insulating film, for example, using a plasma CVD method. In other words, an amorphous silicon thin film is formed (deposited) on the entire face of the substrate 30. Finally, a silicon dioxide (SiO₂) film is formed on the amorphous silicon thin film. Then, by using the laser irradiation device 10 illustrated in FIG. 1, laser light 14 is emitted onto a predetermined area on a gate electrode of an amorphous silicon thin film (an area that becomes a channel region in the thin film transistor) to perform an annealing process, and the predetermined area is polycrystallized such that it becomes polysilicon. In addition, for example, the substrate 30 is a glass substrate, but the substrate 30 does not necessarily need to be formed using a glass material and may be a substrate formed using a certain material such as a resin substrate formed using a material such as a resin or the like.

As illustrated in FIG. 1, in the laser irradiation device 10, the beam system of laser light emitted from a laser light source 11 is expanded by a coupling optical system 12, and a luminance distribution of the laser light is made uniform. The laser light source 11, for example, may be an excimer laser that emits laser light of which a wavelength is 308 nm, 248 nm or the like using a predetermined repetition period. In addition, the wavelength is not limited to such an example and may be any wavelength.

Thereafter, the laser light is transmitted through a plurality of openings (transmission areas) of a projection mask 15 disposed on a microlens array 13, split into a plurality of pieces of laser light 14, and emitted onto a predetermined area of an amorphous silicon thin film formed as a coating film on the substrate 30. The projection mask pattern 15 is disposed in the microlens array 13, and the laser light 14 emitted onto a predetermined area in accordance with the projection mask pattern 15. Then, a predetermined area of the amorphous silicon thin film is instantaneously heated and melted, and the amorphous silicon thin film becomes a polysilicon thin film.

The polysilicon thin film has an electron mobility higher than that of the amorphous silicon thin film and is used in a channel region electrically connecting a source to a drain in a thin film transistor. In addition, in the example illustrated in FIG. 1, although an example using the microlens array 13 is illustrated, the microlens array 13 does not necessarily need to be used, and laser light 14 may be emitted using one projection lens. In addition, in the first example, when a polysilicon thin film is formed using the microlens array 13 will be described as an example.

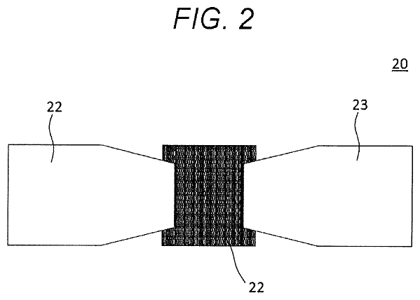

FIG. 2 is a diagram illustrating an example of a thin film transistor 20 in which a predetermined area is processed by annealing. In addition, the thin film transistor 20 is generated by forming a polysilicon thin film 22 first and thereafter forming a source 23 and a drain 24 at both ends of the formed polysilicon thin film 22.

In the thin film transistor illustrated in FIG. 2, as a result of the annealing processing, one polysilicon thin film 22 is formed between the source 23 and the drain 24. In addition, the laser irradiation device 10 illustrated in FIG. 1 emits laser light 14 to one thin film transistor 20, for example, using 20 microlenses 17 included in one column (or one row) of the microlens array 13. In other words, the laser irradiation device 10 emits 20 shots of laser light 14 to one thin film transistor 20. As a result, in the thin film transistor 20, predetermined areas of the amorphous silicon thin film 21 are instantaneously heated and melted such that they become a polysilicon thin film 22. In addition, in the laser irradiation device 10, the number of microlenses included in one column (or one row) of the microlens array 13 is not limited to 20 and may be any number that is equal to or greater than two.

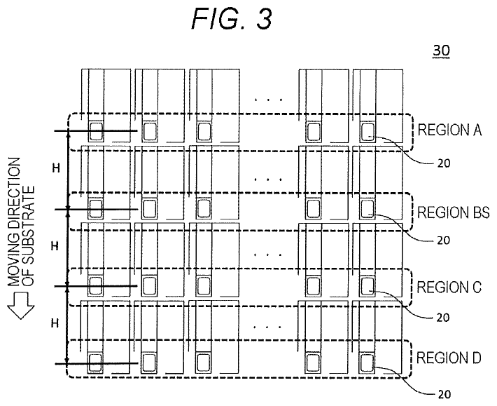

FIG. 3 is a diagram illustrating an example of a substrate 30 after the laser irradiation device 10 illustrated in FIG. 1 emits laser light 14. As illustrated in FIG. 3, the substrate 30 includes a plurality of pixels, and a thin film transistor 20 is included in each of the pixels. The thin film transistor 20 executes light transmission control in each of the plurality of pixels by performing electrical turn-on/off. As illustrated in FIG. 3, thin film transistors 20 are disposed at a predetermined interval “H” in the substrate 30. For this reason, the laser irradiation device 10 illustrated in FIG. 1 needs to emit laser beam onto an amorphous silicon thin film formed as a coating film on the substrate 30 at a predetermined interval “H.” In addition, predetermined areas of the amorphous silicon thin film 21 are parts processed by annealing and become thin film transistors 20.

The laser irradiation device 10 illustrated in FIG. 1 emits laser light 14 onto predetermined areas of the amorphous silicon thin film formed as a coating film on the substrate 30. The laser irradiation device 10 emits laser light 14 using a predetermined cycle time, moves the substrate 30 at a time at which the laser light 14 is not emitted, and emits the laser light 14 to predetermined areas of the next amorphous silicon thin film. As illustrated in FIG. 3, the predetermined areas processed by annealing and become thin film transistors 20 are arranged at a predetermined interval “H” with respect to a moving direction of the substrate 30. The laser irradiation device 10 emits laser light 14 onto predetermined areas of the amorphous silicon thin film formed as a coating film on the substrate 30 using a predetermined cycle time.

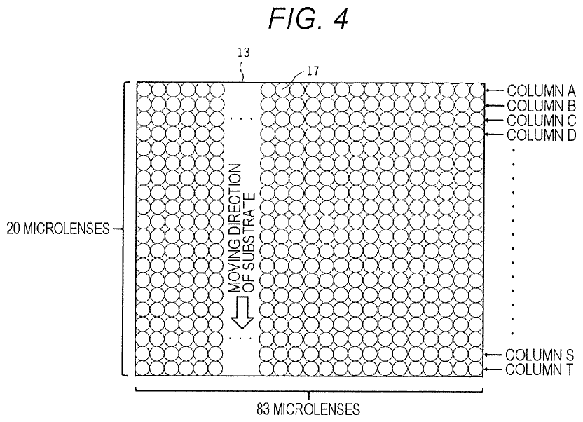

FIG. 4 is a diagram illustrating a configuration of the microlens array 13. As illustrated in FIG. 4, the laser irradiation device 10 illustrated in FIG. 1 emits laser light 14 onto predetermined areas of the amorphous silicon thin film formed as a coating film on the substrate 30 and forms the predetermined areas as polysilicon thin films by sequentially using a plurality of microlenses 17 included in the microlens array 13. As illustrated in FIG. 4 as an example, the number of microlenses 17 included in one column (or one row) of the microlens array 13 is 20. Then, laser light is emitted to one predetermined area using 20 microlenses 17 (in other words, microlenses 17 included in one column). In addition, the number of microlenses 17 included in one column (or one row) of the microlens array 13 is not limited to 20 and may have any value. Furthermore, the number of microlenses 13 included in one row (or one column) of the microlens array 13 is not limited to 83 illustrated in FIG. 4 as an example and may have any value.

The laser irradiation device 10 illustrated in FIG. 1, first emits laser light 14 onto predetermined areas of a region A of the substrate 30 illustrated in FIG. 3 using first microlenses 17 included in the microlens array 13 (for example, microlenses 17 disposed in a column T of the microlens array illustrated in FIG. 4). Thereafter, the substrate 30 is moved by the predetermined interval “H.” While the substrate 30 is moving, the laser irradiation device 10 stops emission of laser light 14. Then, after the substrate 30 is moved by “H,” the laser irradiation device 10 emits laser light 14 onto predetermined areas of a region B of the substrate 30 illustrated in FIG. 3 using first microlenses 17 included in the microlens array 13 (in other words, microlenses 17 disposed in a column T of the microlens array illustrated in FIG. 4). In this example, the laser light 14 is emitted to predetermined areas of the region A illustrated in FIG. 4 using second microlenses 17 adjacent to the first microlenses 17 in the microlens array 13 (in other words, microlenses 17 disposed in a column S of the microlens array illustrated in FIG. 4). In this way, the laser light 14 is emitted to predetermined areas included in the substrate 30 respectively by a plurality of microlenses 17 corresponding to one column (or one row) of the microlens array 13.

In addition, the laser irradiation device 10 may emit laser light 14 onto the substrate 30 that has temporarily stopped after the substrate 30 moves by “H” or may emit laser light 14 onto the substrate 30 that is continuously moving. Furthermore, the laser irradiation device 10 may continue to emit laser light 14 also while the substrate 30 is moving.

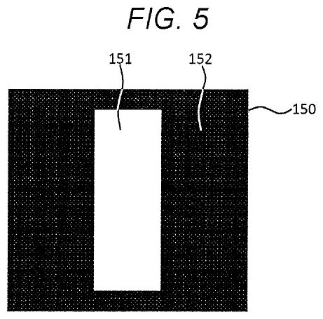

FIG. 5 is a diagram illustrating a configuration of a projection mask 150 included in the projection mask pattern 15. The projection mask 150 corresponds to the microlens 17 included in the microlens array 13 illustrated in FIG. 4. In the example illustrated in FIG. 5, the projection mask 150 includes a transmission area 151 and a light shielding area 152. The laser light 14 is transmitted through the transmission area 151 of the projection mask 150 and emitted to a channel region of the thin film transistor 20. The transmission area 151 of the projection mask 150 has a width (a length of a short side) of about 50 μm. In addition, the length of the width is merely an example and may be any length. In addition, the length of a long side of the projection mask 150, for example, is about 100 μm. Furthermore, the length of the long side is merely an example and may be any length.

In addition, the microlens array 13 illustrated in FIG. 4 emits laser light, for example, by reducing the projection mask 150 by ⅕. As a result, the laser light 14 that has been transmitted through the projection mask 150 is reduced to have a width of about 10 μm and a length of about 20 μm in a channel region. The reduction ratio of the microlens array 13 is not limited to ⅕ and may be any scale.

In addition, the projection mask pattern 15 is formed by aligning projection masks 150 illustrated in FIG. 5 as an example corresponding to at least the number of microlenses 17.

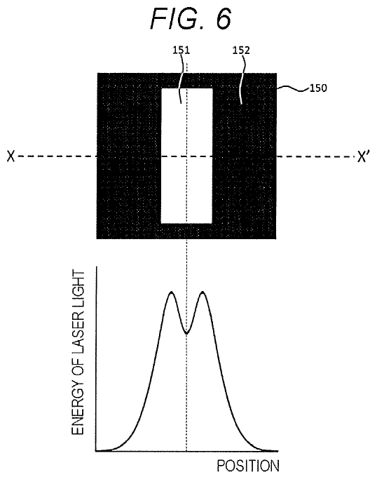

FIG. 6 is a graph representing an energy status of laser light in a channel region when the laser light is emitted using the projection mask 150 illustrated in FIG. 5 as an example. The graph illustrated in FIG. 6 represents an emission energy state of laser light at a position corresponding to line X-X′ parallel to the short side of the projection mask 15 in a predetermined area of the substrate 30. In the graph illustrated in FIG. 6, the horizontal axis is a position, and the vertical axis is emission energy (emission energy in a channel region) of laser light at the position. In addition, the example illustrated in FIG. 6 is merely one example, and it is apparent that the status of emission energy of laser light in the channel region changes in accordance with energy of the laser light, the size of the projection mask 150 and the like.

As illustrated in FIG. 6, energy of laser light that hashaving passed a peripheral portion (edge portion) of the projection mask 150 is higher than energy of laser light having passed other portions in the channel region. When energy emitted by laser light is high, a speed at which the amorphous silicon thin film is crystallized becomes high. For this reason, the speed of crystallization of the peripheral portion (edge portion) of the channel region (crystallization of amorphous silicon) is higher than that of the other portions. In other words, the peripheral portion (edge portion) of the channel region is crystallized earlier than the other portions.

For this reason, the degree of crystallization of polysilicon crystal is biased within the channel region, the characteristics of the formed polysilicon thin film become non-uniform, and deviations occur in the characteristics of individual thin film transistors included in the substrate. As a result, there is a problem of occurrence of display blurs in a liquid crystal generated using the substrate.

Thus, in the projection mask 150 according to the first example, other transmission areas (auxiliary patterns) are disposed at both ends of the transmission area 151.

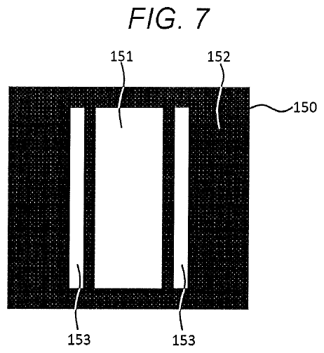

FIG. 7 is a schematic diagram illustrating a configuration example of a projection mask 150 when auxiliary patterns 153 are disposed. As illustrated in FIG. 7, the auxiliary patterns 153, for example, are narrow slits along a long side (in the longitudinal direction) of a transmission area 151. In addition, the shape of the auxiliary patterns 153 is not limited to the shape of the narrow slits but may be any shape, and a preferred shape according to the shape of the projection mask 150 can be formed.

While the length (the long side) of the auxiliary pattern 153 is similar to that of the transmission area 151, the width thereof, for example, is about 1/10 of the transmission area 151. For example, when the width (the length of the short side) of the transmission area 151 is about the width (the length of the short side) of the auxiliary pattern 153 is about 5 μm. In addition, the width (the length of the short side) of the auxiliary pattern 153 may be any length as long as the length is a length for which emission energy of laser light passing through an edge portion of the transmission area 151 on the substrate 30 can be reduced and is not limited to the length that is 1/10 of the transmission area 151.

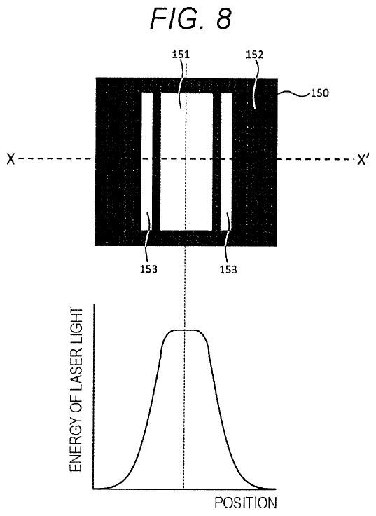

FIG. 8 is a graph representing an energy status of laser light in a channel region when the laser light is emitted using the projection mask 150 in which the auxiliary patterns 153 are arranged. The graph illustrated in FIG. 8 illustrates emission energy status of laser light at a position corresponding to a line X-X′ parallel to the short side of the projection mask 15 in a predetermined area of the substrate 30. In the graph illustrated in FIG. 8, the horizontal axis is a position, and the vertical axis is emission energy (emission energy in the channel region) of laser light at the position. In addition, the example illustrated in FIG. 8 is merely one example and, similar to FIG. 6, it is apparent that the status of energy of laser light in the channel region changes in accordance with energy at the time of emitting the laser light, the size of the projection mask 150 and the like.

As illustrated in FIG. 8, the energy of laser light having passed through the projection mask 150 in which the auxiliary patterns 153 are disposed is energy of a same degree as the energy of laser light having passed through any other portions in the channel region. In other words, different from the example illustrated in FIG. 6, the energy of laser light having passed through the projection mask 150 in which the auxiliary patterns 153 are disposed is not higher in the edge portion of the projection mask 150 than in any other portion. In other words, by using the projection mask 150 in which the auxiliary patterns 153 are disposed, the energy of laser light emitted onto the channel region becomes uniform. As a result, laser light having uniform energy can be emitted onto the channel region, and the degree of crystallization of polysilicon crystal becomes uniform. For this reason, variations in the characteristics of a plurality of thin film transistors included in the substrate can be inhibited.

In addition, the auxiliary patterns 153 may be disposed also in the widthwise direction (the short side direction) of the transmission area 151.

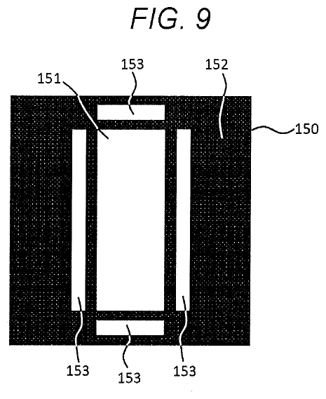

FIG. 9 is a diagram illustrating a configuration example of a projection mask 150 when auxiliary patterns 153 are also disposed in a widthwise direction of a transmission area 151. When the auxiliary patterns 153 are not disposed, also in the widthwise direction of the transmission area 151, the energy of laser light 14 having transmitted through the edge area of the transmission area 151 is higher than the energy of laser light 14 having passed through any other area. For this reason, the speed of crystallization of the peripheral portion (the edge portion) of the channel region (crystallization of amorphous silicon) is higher than that of the other portions. In this way, the peripheral portion (the edge portion) of the channel region is crystallized more quickly than the other portions and, accordingly, the degree of crystallization of polysilicon crystal is biased within the channel region.

Thus, as illustrated in FIG. 9, in the projection mask 150, the auxiliary patterns 153 are also disposed in the widthwise direction of the transmission area 151, deviations in the energy of laser light in the channel region is resolved, and laser light having uniform energy is emitted. As a result, the degree of crystallization of polysilicon crystal is made uniform, and variations in the characteristics of a plurality of thin film transistors included in the substrates can be inhibited.

Next, a method of generating the thin film transistor 20 illustrated in FIG. 2 using the laser irradiation device 10 will be described.

First, the laser irradiation device 10 illustrated in FIG. 1 emits laser light 14 onto a predetermined area on the substrate 30 through the projection mask pattern 15 including the projection mask 150 illustrated in FIG. 7 or 9 using the microlenses 17 included in the microlens array 13. As a result, an amorphous silicon thin film formed as a coating film on the substrate 30 is instantaneously heated and melted and becomes a polysilicon thin film.

The substrate 30 is moved by a predetermined distance every time laser light 14 is emitted by one microlens 17. The predetermined distance, as illustrated in FIG. 3 as an example, is a distance “H” between a plurality of thin film transistors 20 in the substrate 30. The laser irradiation device 10 stops emission of the laser light 14 while moving the substrate 30 by the predetermined distance.

After the substrate 30 is moved by the predetermined distance “H,” the laser irradiation device 10 emits laser light 14 onto a predetermined area emitted by one microlens 17 again using another microlens 17 included in the microlens array 13. As a result, the amorphous silicon thin film formed as a coating film on the substrate 30 is instantaneously heated and melted one more time and becomes a polysilicon thin film.

By repeating the process described above, laser light 14 corresponding to 20 shots is emitted to each of predetermined areas on the substrate 30 through the projection mask pattern 15 illustrated in FIG. 7 or 9, for example, by sequentially using 20 microlenses 17. As a result, a polysilicon thin film is formed in a predetermined area of the amorphous silicon thin film formed as a coating film on the substrate 30.

Thereafter, in other processes, sources 23 and drains 24 are formed, whereby thin film transistors are formed.

As described above, in the first example, by disposing auxiliary patterns in the surroundings of the transmission area in the projection mask, deviations in the energy of laser light in the channel region are resolved. For this reason, the degree of crystallization of the polysilicon crystal is made uniform, and variations in the characteristics of a plurality of thin film transistors included in the substrate can be inhibited. As a result, occurrence of display blurs in the liquid crystal generated using the substrate can be inhibited.

### SECOND EXAMPLE

According to a second example, by arranging a plurality of light shielding parts in a peripheral area (edge area) of a projection mask, a part of laser light passing through the peripheral area is shielded. In this way, since the energy of laser light in the peripheral area of the projection mask 150 is reduced, the energy of laser light in the entire channel region can be made uniform.

A configuration of a laser irradiation device according to the second example is similar to that of the laser irradiation device 10 according to the first example illustrated in FIG. 1, and thus a detailed description thereof will be omitted.

When laser light is emitted without arranging the light shielding parts, as illustrated in FIG. 6, the energy of laser light passing through an edge area of the transmission area 151 becomes high in a channel region, which becomes a factor increasing the speed of crystallization of the edge area. Thus, in the second example, light shielding parts shielding laser light are arranged in an edge area of a transmission area 151 of a projection mask 150, and the amount (magnitude) of laser light passing through the edge area is adjusted. In addition, the arrangement of light shielding parts is not limited to the edge area of the transmission area 151, and the light shielding parts may be arranged in any area as long as the area is an area in which the amount (magnitude) of laser light is larger than in the other areas.

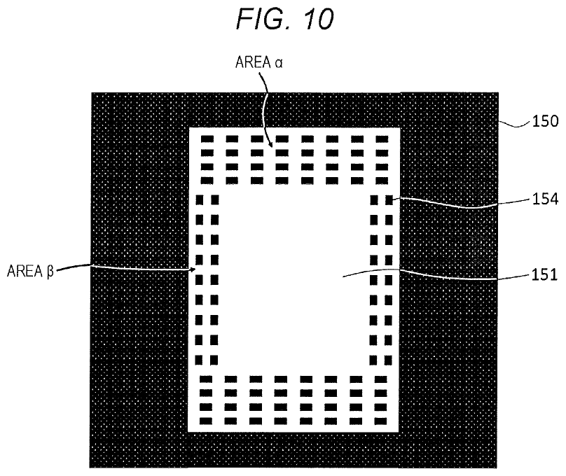

FIG. 10 is a diagram illustrating a configuration example of a projection mask 150 according to the second example.

As illustrated in FIG. 10, in a peripheral area (edge area) of the projection mask 150, a plurality of light shielding parts 154 are disposed. In the example illustrated in FIG. 10, the light shielding parts 154 are disposed to be arranged in an edge area (an area α) in a widthwise direction of the transmission area 151 and an edge area (an area β) in a longitudinal direction. In the example illustrated in FIG. 10, for example, in the area α, light shielding parts are arranged in four columns with an interval of about 1 μm interposed therebetween. In addition, in the area β, light shielding parts are arranged in two columns with an interval of about 2 μm interposed therebetween. Furthermore, the arrangement of such light shielding parts 154 are merely examples, and the light shielding parts may be arranged in a difference way.

In addition, the light shielding part 154, for example, is a rectangle of which one side is about 1 μm. Furthermore, the light shielding part 154 is not limited to a rectangle of about 1 μm and may have any size and any shape as long as they are less than the resolving power of the microlens array.

In addition, the number of light shielding parts 154 disposed in the projection mask 150 may be determined on the basis of the transmittance of laser light. In the example illustrated in FIG. 10, the number light shielding parts 154 disposed in the edge area (area α) in the widthwise direction of the transmission area 151 is larger than the number of light shielding parts disposed in the edge area (area β) in the longitudinal direction. In other words, the density of the light shielding parts 154 in the widthwise direction of the transmission area 151 is higher than the density of the light shielding parts 154 of the edge area in the longitudinal direction. In this way, the number (density) of light shielding parts 154 can be adjusted in accordance with deviations in the energy of the laser light 14 in the channel region.

In addition, in the example illustrated in FIG. 10, although the light shielding parts 154 are disposed in the entire edge area of the transmission area 151, for example, the light shielding parts 154 may be disposed only in the edge area (area β) in the longitudinal direction or, to the contrary, may be disposed only in the edge area (area α) in the widthwise direction.

As described above, in the second example, by arranging light shielding parts in the transmission area of the projection mask, a part of laser light passing through the transmission area can be shielded. As a result, the energy of laser light emitted to predetermined areas on the substrate can be adjusted. For this reason, for example, by disposing light shielding parts in a portion in which the energy of emission of laser light is higher than that in the other portions, the energy of the laser light in the entire predetermined area can be made uniform. For this reason, the degree of crystallization of polysilicon crystal is made uniform, and variations in the characteristics of a plurality of thin film transistors included in the substrate can be inhibited. As a result, occurrence of display blurs in liquid crystal generated using the substrate can be prevented.

### THIRD EXAMPLE

According to a third example, auxiliary patterns are disposed in a projection mask, and light shielding parts are disposed within a transmission portion, whereby the energy of laser light in a channel region is made uniform.

A configuration of a laser irradiation device according to the third example is similar to that of the laser irradiation device 10 according to the first example illustrated in FIG. 1, and thus a detailed description thereof will be omitted.

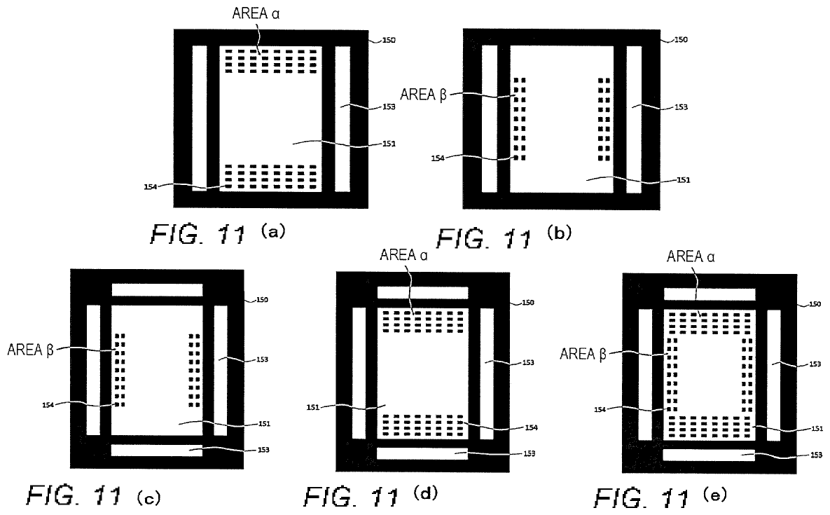

FIG. 11 is a diagram illustrating a configuration example of a projection mask 150 according to the third example.

As illustrated in FIG. 11(a), in the projection mask 150, auxiliary patterns 153 are disposed in a long side direction of the transmission area 151, and light shielding parts 154 are disposed in edge areas (areas α) in the widthwise direction of the transmission area 151.

Since the auxiliary patterns 153 are disposed in the long side direction of the transmission area 151, as illustrated in FIG. 8, the energy of laser light in the channel region can be made uniform.

Since the light shielding parts 154 are disposed in the edge areas (areas α) in the widthwise direction of the transmission area 151, the amount (magnitude) of laser light 14 to be passed can be adjusted, and the energy of the laser light 14 in the channel region can be reduced.

As described above, by emitting laser light using the projection mask 150 illustrated in FIG. 11(a), laser light having uniform energy can be emitted to a predetermined area, and the degree of crystallization of polysilicon crystal is made uniform. For this reason, variations in the characteristics of a plurality of thin film transistors included in the substrate can be inhibited.

In addition, as illustrated in FIG. 11(b), in the projection mask 150, together with disposing auxiliary patterns 153 in the widthwise direction of the transmission area 151, light shielding parts 154 may be disposed in edge areas (areas β) in the long side direction of the transmission area 151.

Since the auxiliary patterns 153 are disposed in the widthwise direction of the transmission area 151, as illustrated in FIG. 8, the energy of laser light 14 in the channel region can be made uniform.

In addition, since the light shielding parts 154 are disposed in the edge areas (areas β) in the long side direction of the transmission area 151, the amount (magnitude) of laser light to be passed can be adjusted, and the energy of the laser light in the channel region can be reduced.

As described above, by emitting laser light using the projection mask 150 illustrated in FIG. 11(b), laser light having uniform energy can be emitted to a predetermined area, and the degree of crystallization of polysilicon crystal is made uniform. For this reason, variations in the characteristics of a plurality of thin film transistors included in the substrate can be inhibited.

In addition, as illustrated in FIG. 11(c), in the projection mask 150, together with disposing auxiliary patterns 153 in the widthwise direction and the long side direction of the transmission area 151, light shielding parts 154 may be disposed in edge areas (areas β) in the long side direction of the transmission area 151.

Since the auxiliary patterns 153 are disposed in the widthwise direction and the long side direction of the transmission area 151, as illustrated in FIG. 8, the energy of laser light 14 in a predetermined area can be made uniform.

In addition, since the light shielding parts 154 are disposed in the edge areas (areas β) in the long side direction of the transmission area 151, the amount (magnitude) of laser light 14 to be passed can be adjusted, and the energy of the laser light 14 in the predetermined area can be reduced.

The energy of the laser light 14 can be finely adjusted using the size and the number of the light shielding parts 154. In the example illustrated in FIG. 11(c), since the auxiliary patterns 153 and the light shielding parts 154 are disposed in the long side direction, after the energy of emission of the laser light 14 is greatly adjusted using the auxiliary patterns 153, by appropriately disposing the light shielding parts 154 additionally, the energy of the laser light 14 can be finely adjusted, and uniformization of the energy of the laser light 14 in the predetermined area can be further improved.

In addition, as illustrated in FIG. 11(d), in the projection mask 150, together with disposing auxiliary patterns 153 in the widthwise direction and the long side direction of the transmission area 151, light shielding parts 154 may be disposed in edge areas (areas α) in the widthwise direction of the transmission area 151.

Since the auxiliary patterns 153 are disposed in the widthwise direction and the long side direction of the transmission area 151, as illustrated in FIG. 8, the energy of laser light 14 in a predetermined area can be made uniform.

In addition, since the light shielding parts 154 are disposed in the edge areas (areas α) in the widthwise direction of the transmission area 151, the amount (magnitude) of laser light 14 to be passed can be adjusted, and the energy of the laser light 14 in the predetermined area can be reduced.

In FIG. 11(d), since the auxiliary patterns 153 and the light shielding parts 154 are disposed in the widthwise direction, after the energy of emission of the laser light 14 is greatly adjusted using the auxiliary patterns 153, by appropriately disposing the light shielding parts 154 additionally, the energy of the laser light 14 can be finely adjusted, and uniformization of the energy of the laser light 14 in the predetermined area can be further improved.

Furthermore, as illustrated in FIG. 11(e), in the projection mask 150, together with disposing auxiliary patterns 153 in the widthwise direction and the long side direction of the transmission area 151, light shielding parts 154 may be disposed in edge areas (areas α and β) in the widthwise direction and the long side direction of the transmission area 151.

Since the auxiliary patterns 153 are disposed in the widthwise direction and the long side direction of the transmission area 151, as illustrated in FIG. 8, the energy of laser light 14 in a predetermined area can be made uniform.

In addition, since the light shielding parts 154 are disposed in the edge areas (areas α and β) in the widthwise direction and the long side direction of the transmission area 151, the amount (magnitude) of laser light 14 to be passed can be adjusted, and the energy of the laser light 14 in the predetermined area can be reduced.

In FIG. 11(e), since the auxiliary patterns 153 and the light shielding parts 154 are disposed in the widthwise direction and the long side direction, after the energy of emission of the laser light 14 is greatly adjusted using the auxiliary patterns 153, by appropriately disposing the light shielding parts 154 additionally, the energy of the laser light 14 can be finely adjusted, and uniformization of the energy of the laser light 14 in the predetermined area can be further improved.

As described above, in the third example, by also arranging the light shielding parts within the transmission area together with disposing the auxiliary patterns in the projection mark, the energy of laser light in a predetermined area is made uniform. For this reason, the degree of crystallization of polysilicon crystal is made uniform, and variations in the characteristics of a plurality of thin film transistors included in the substrate can be inhibited. As a result, occurrence of display blurs in liquid crystal generated using the substrate 30 can be prevented.

### FOURTH EXAMPLE

A fourth example describes when laser annealing is performed using one projection lens instead of a microlens array including a plurality of microlenses.

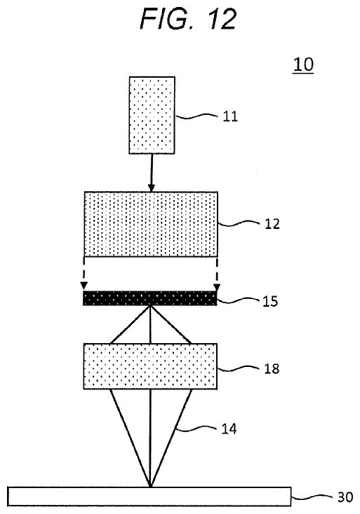

FIG. 12 is a diagram illustrating a configuration of a laser irradiation device 10 according to the fourth example. As illustrated in FIG. 12, a laser irradiation device 10 according to the fourth example includes a laser light source 11, a coupling optical system 12, a projection mask pattern 15, and a projection lens 18. In addition, the laser light source 11 and the coupling optical system 12 have configurations similar to the laser light source 11 and the coupling optical system 12 according to the first example illustrated in FIG. 1, and thus a detailed description thereof will be omitted.

Laser light is transmitted through a plurality of openings (transmission areas) of the projection mask pattern 15 and emitted onto a predetermined area of an amorphous silicon thin film formed as a coating film on a substrate 30 in accordance with the projection lens 18. As a result, the predetermined area of the amorphous silicon thin film is instantaneously heated and melted, and a part of the amorphous silicon thin film becomes a poly silicon thin film.

In the fourth example, a projection mask included in the projection mask pattern 15 as illustrated in FIG. 7, is the projection mask 150 in which the auxiliary patterns 153 are disposed in the surroundings of the transmission area 151. In this way, since the auxiliary patterns 153 are disposed in the long side direction of the transmission area 151, as illustrated in FIG. 8, the energy of laser light 14 in a predetermined area can be made uniform.

In addition, in the fourth example, the projection mask 150 included in the projection mask pattern 15 may be a projection mask in which a plurality of light shielding parts 154 are disposed in peripheral areas (edge areas). For example, in the example illustrated in FIG. 10, light shielding parts 154 are disposed to be arranged in edge areas (areas α) in the widthwise direction of the transmission area 151 and edge areas (areas β) in the longitudinal direction. As a result, the laser light 14 emitted onto a channel region can be adjusted. For this reason, for example, by disposing light shielding parts 154 in a portion in which the energy of emission of laser light 14 is higher than that in the other portions, the energy of the laser light 14 in the entire predetermined area can be made uniform.

In addition, in the fourth example, a projection mask 150 included in the projection mask pattern 15 may be a projection mask 150 illustrated in FIGS. 11(a) to 11(e) as examples. In this way, by arranging light shielding parts 154 within the transmission area 151 together with arranging auxiliary patterns 153 in the projection mask 150, the energy of laser light 14 in a predetermined area can be made uniform.

Also, in the fourth example, the laser irradiation device 10 illustrated in FIG. 12 emits laser light 14 at a predetermined period, moves the substrate 30 in a time in which the laser light 14 is not emitted and causes the laser light 14 to be emitted to a portion of the next amorphous silicon thin film 21. Also, in the second example as illustrated in FIG. 3, in the substrate 30, thin film transistors 20 are disposed at a predetermined interval “H” in the moving direction. Thus, the laser irradiation device 10 emits laser light 14 onto a predetermined area of an amorphous silicon thin film deposited in the substrate 30 at a predetermined period.

When the projection lens 18 is used, the laser light 14 is converted at the magnification of the optical system of the projection lens 18. In other words, the pattern of the projection mask pattern 15 is converted at the magnification of the optical system of the projection lens 18, and a predetermined area on the substrate 30 is annealed by laser. Since the magnification of the optical system of the projection lens 18 is about two times, the mask pattern of the projection mask pattern 15 becomes about ½ (0.5) times, and a predetermined area of the substrate 30 is annealed by laser. In addition, magnification of the optical system of the projection lens 18 is not limited to about two times but may be any magnification. In the mask pattern of the projection mask pattern 15, a predetermined area on the substrate 30 is annealed by laser in accordance with the magnification of the optical system of the projection lens 18. For example, when the magnification of the optical system of the projection lens 18 is four times, the mask pattern of the projection mask pattern 15 becomes about ¼ (0.25), and a predetermined area of the substrate 30 is laser-annealing processed.

In addition, when the projection lens 18 forms an inverted image, a reduced image of the projection mask pattern 15 that is emitted to the substrate 30 becomes a pattern rotated around the optical axis of the projection lens 18 by 180 degrees. On the other hand, when the projection lens 18 forms an erect image, a reduced image of the projection mask pattern 15 emitted to the substrate 30 becomes the projection mask pattern 15 as it is. In the example illustrated in FIG. 10, since the projection lens 18 forming an erect image is used, the pattern of the projection mask pattern 15 is reduced as it is on the substrate 30.

As described above, in the fourth example, when the projection lens 18 is used, as the projection mask 150 included in the projection mask pattern 15, a projection mask in which auxiliary patterns 153 are disposed in the surroundings of the transmission area 151, a projection mask in which a plurality of light shielding parts 154 are disposed in peripheral areas (edge areas), or a projection mask including both thereof may be used. For this reason, also when the projection lens 18 is used, the energy of laser light 14 in a predetermined area can be made uniform. For this reason, the degree of crystallization of polysilicon crystal is made uniform, and variations in the characteristics of a plurality of thin film transistors included in the substrate 30 can be inhibited. As a result, occurrence of display blurs in liquid crystal generated using the substrate 30 can be prevented.

In addition, when there is a description of “vertical,” “parallel,” “plane surface” or the like in the description above, such a description is not in the strict sense. In other words, “vertical,” “parallel” and “plane surface” respectively have meanings of “substantially vertical,” “substantially parallel” and “substantially plane surface” with tolerance or error in the design or manufacturing allowed. In addition, tolerance or error described here represents a unit in a range not departing from the configurations, the operations, and the desired effects.

In addition, when there is a description of a size or a magnitude in appearance being “the same,” “equal,” “different” and the like, such descriptions are not in the strict sense. In other words, “the same,” “equal” and “different” respectively have meanings of “substantially the same,” “substantially equal” and “substantially different” with tolerance or error in the design or manufacturing allowed. In addition, tolerance or error described here represents a unit in a range not departing from the configurations, the operations, and the desired effects.

While my devices, methods, programs and masks have been described with reference to the drawings and the examples, it should be noted that those skilled in the art can easily perform various modifications and corrections on the basis of this disclosure. Thus, it should be noted such modifications and corrections belong to the scope of the disclosure. For example, means and functions included in steps and the like may be rearranged such that they are not logically contradictory to each other, and a plurality of means, steps, and the like may be either combined into one or further divided. In addition, the components illustrated in the examples described above may be appropriately combined.

1-18. (canceled)

19. A laser irradiation device comprising:
a light source that generates laser light;
a projection lens that emits the laser light onto a predetermined area of an amorphous silicon thin film deposited on a thin film transistor; and
a projection mask pattern disposed in the projection lens and transmits the laser light in a predetermined projection pattern,
wherein the projection mask pattern includes auxiliary patterns disposed in the surroundings of a transmission area corresponding to the predetermined area in addition to the transmission area and transmits the laser light.

20. The laser irradiation device according to claim 19,
wherein the projection lens is a plurality of microlenses included in a microlens array that can split the laser light, and
each of a plurality of masks included in the projection mask pattern corresponds to each of the plurality of microlenses.

21. The laser irradiation device according to claim 19, wherein the projection mask pattern includes auxiliary patterns having an approximately rectangular shape disposed in a long side direction or a short side direction of a transmission area in addition to the transmission area having an approximately rectangular shape and having a width narrower than the transmission area.

22. The laser irradiation device according to claim 19, wherein the projection mask pattern includes second auxiliary patterns disposed in a short side direction of the transmission area in addition to first auxiliary patterns disposed in a long side direction of the transmission area having an approximately rectangular shape.

23. The laser irradiation device according to claim 19, wherein, in the projection mask pattern, a width or a size of the auxiliary patterns is determined on a basis of an energy of the laser light in the predetermined area.

24. The laser irradiation device according to claim 19, wherein, in the projection mask pattern, a plurality of light shielding parts shielding the laser light are disposed in edge areas within the transmission area in a long side direction or a short side direction of the transmission area.

25. The laser irradiation device according to claim 19, wherein, in the projection mask pattern, a plurality of light shielding parts shielding the laser light are disposed in edge areas within the transmission area in a long side direction and a short side direction of the transmission area, and densities of the light shielding parts disposed in the edge areas in the long side direction and the edge areas in the short side direction are different from each other.

26. The laser irradiation device according to claim 24, wherein, in the projection mask pattern, a density of the light shielding parts disposed within the transmission area is determined in accordance with an energy of the laser light in the predetermined area.

27. A method of manufacturing a thin film transistor comprising:
a generation step of generating laser light;
a transmission step of transmitting the laser light in a predetermined projection pattern disposed in a projection lens; and
an emission step of emitting the laser light transmitted through the predetermined projection pattern onto a predetermined area of an amorphous silicon thin film deposited in a thin film transistor,
wherein, in the transmission step, the laser light is transmitted through auxiliary patterns disposed in surroundings of a transmission area corresponding to the predetermined area in addition to the transmission area.

28. A program causing a computer to execute:
a generation function of generating laser light;
a transmission function of transmitting the laser light in a predetermined projection pattern disposed in a projection lens; and
an emission function of emitting the laser light transmitted through the predetermined projection pattern onto a predetermined area of an amorphous silicon thin film deposited in a thin film transistor,
wherein, in the transmission function, the laser light is transmitted through auxiliary patterns disposed in surroundings of a transmission area corresponding to the predetermined area in addition to the transmission area.

29. A projection mask disposed in a projection lens emitting laser light, the projection mask comprising:
a first mask pattern that transmits the laser light in a predetermined projection pattern for a predetermined area of an amorphous silicon thin film deposited in a thin film transistor; and
a second mask pattern disposed in the surroundings of the first mask pattern corresponding to the predetermined area in addition to the first mask pattern and transmits the laser light.

30. The projection mask according to claim 29,
wherein the projection lens is a plurality of microlenses included in a microlens array that can split the laser light, and
each of a plurality of masks included in the first mask pattern corresponds to each of the plurality of microlenses.

31. The projection mask according to claim 29, wherein the second mask pattern includes auxiliary patterns having an approximately rectangular shape disposed in a long side direction or a short side direction of a transmission area in addition to the transmission area having an approximately rectangular shape and having a width narrower than the transmission area.

32. The projection mask according to claim 29, wherein the second mask pattern includes patterns disposed in a short side direction of the transmission area in addition to patterns disposed in a long side direction of the transmission area having an approximately rectangular shape.

33. The projection mask according to claim 29, wherein a width or a size of the second mask pattern is determined on the basis of an energy of the laser light in the predetermined area.

34. The projection mask according to claim 29, wherein, in the second mask pattern, a plurality of light shielding parts shielding the laser light are disposed in edge areas within the transmission area in a long side direction or a short side direction of the transmission area.

35. The projection mask according to claim 29, wherein, in the second mask pattern, a plurality of light shielding parts shielding the laser light are disposed in edge areas within the transmission area in a long side direction and a short side direction of the transmission area, and densities of the light shielding parts disposed in the edge areas in the long side direction and the edge areas in the short side direction are different from each other.

36. The projection mask according to claim 34, wherein, in the second mask pattern, a density of the light shielding parts disposed within the transmission area is determined in accordance with an energy of the laser light in the predetermined area.
